(19) United States
(12) Patent Application Publication
(10) Pub. No.: US 2011/0266611 A1
(43) Pub. Date: Nov. 3, 2011

(54) NONVOLATILE MEMORY DEVICE AND METHOD FOR FABRICATING THE SAME

(76) Inventors: Beom-Yong KIM, Gyeonggi-do (KR); Ki-Hong LEE, Gyeonggi-do (KR)

(21) Appl. No.: 12/981,298

(22) Filed: Dec. 29, 2010

(30) Foreign Application Priority Data
Apr. 29, 2010 (KR) 10-2010-0040171

(51) Int. Cl. H01L 29/792; H01L 21/28

(52) U.S. Cl. 257/324; 438/588; 257/E29.309; 257/E21.21

(57) ABSTRACT

A nonvolatile memory device includes a plurality of interlayer dielectric layers and conductive layers for gate electrodes alternately stacked over a substrate, a channel trench passing through the interlayer dielectric layers and the conductive layers and exposing the substrate, a charge blocking layer and a charge trap or charge storage layer formed on sidewalls of the trench, a coupling prevention layer formed at the surface of the charge trap or charge storage layer, and a tunnel insulation layer formed over the coupling prevention layer.

### CROSS-REFERENCE TO RELATED APPLICATIONS

The present application claims priority of Korean Patent Application No. 10-2010-0040171, filed on Apr. 29, 2010, which is incorporated herein by reference in its entirety.

### BACKGROUND OF THE INVENTION

Exemplary embodiments of the present invention relate to a semiconductor fabrication technology, and more particularly, to a nonvolatile memory device of a vertical-channel type and a method for fabricating the same.

As the integration degree of semiconductor devices rapidly increases, the difficulty in fabricating the semiconductor devices has been increasing, and the fabrication technology has been reaching its limits. In addressing such limitations, technology for vertically forming memory cells by using a multi-stack structure has been proposed.

A nonvolatile memory device having vertical channels basically uses silicon-oxide-nitride-oxide-silicon (SONOS) cells using a charge trap or charge storage layer. However, the SONOS devices have a feature where the erase speed and the retention characteristic are in a trade-off relation.

More specifically, in implementing a multi-layer cell (MLC), an erasing operation is to be normally performed to secure a sufficient program erase (PE) window, and a large data retention ability, e.g. ten years, is useful for a nonvolatile memory. However, since the erase speed and the retention characteristic are in a trade-off relation, there are difficulties for satisfying both conditions.

In particular, the charge trap or charge storage layer is often formed of a nitride layer. The erase operation characteristic and the retention characteristic become sensitive to the composition ratio of silicon to nitrogen in the nitride layer. That is, when silicon is rich, the charge trap or charge storage layer exhibits an excellent erase operation characteristic, but exhibits a poor retention characteristic. When nitrogen is rich, the charge trap or charge storage layer exhibits the reverse characteristics.

Since a sufficient PE window is desired to implement an MLC, use a nitride layer in which silicon is rich is useful.

Meanwhile, the reason that the retention characteristic of the nitride layer in which silicon is rich may be poor may be described as follows. Extra silicon atoms of the nitride layer easily react with oxygen of a tunnel oxide layer in contact with the nitride layer, and spaces from which the oxygen escapes exist as lacks or vacancies in the tunnel oxide layer (refer to IEEE electron device letters, Vol. 30, No. 3, March 2009, Goel et al.: “ERASE AND RETENTION IMPROVEMENTS IN CTF THROUGH ENGINEERED CHARGE STORAGE LAYER”).

In order to address such features, a method for stacking single nitride layers has been proposed. However, when a multilayer is applied, a very thin nitride layer needs to be deposited two-three times. In this case, there are difficulties in forming a nitride layer having a uniform thickness on a hole barrier with a high aspect ratio. Furthermore, as the deposition temperature of the nitride layer is high, thermal stress increases as much, thereby reducing the reliability of a device. When the deposition time of furnace type low-pressure chemical vapor deposition (LPCVD) is considered, the memory fabrication time inevitably increases in comparison with a single nitride layer.

### SUMMARY OF THE INVENTION

An exemplary embodiment of the present invention is directed to a semiconductor memory device and a method for fabricating the same, which is capable of improving the erase operation speed and the retention characteristic.

In accordance with an exemplary embodiment of the present invention, a nonvolatile memory device includes: a plurality of interlayer dielectric layers and conductive layers for gate electrodes alternately stacked over a substrate, a channel trench formed through the interlayer dielectric layers and the conductive layers and exposing the substrate, a charge blocking layer and a charge trap or charge storage layer formed on sidewalk of the trench, a coupling prevention layer formed at the surface of the charge trap or charge storage layer, and a tunnel insulation layer formed over the coupling prevention layer.

In accordance with another exemplary embodiment of the present invention, a method for fabricating a nonvolatile memory device includes: alternately stacking a plurality of interlayer dielectric layers and conductive layers for gate electrodes over a substrate, forming a channel trench exposing the substrate by etching the plurality of interlayer dielectric layers and the plurality of conductive layers, forming a charge blocking layer on sidewalls of the hole, forming a charge trap or charge storage layer over the charge blocking layer, forming a coupling prevention layer at the surface of the charge trap or charge storage layer, and forming a tunnel insulation layer over the coupling prevention layer.

In accordance with yet another exemplary embodiment of the present invention, a nonvolatile memory device includes: a plurality of interlayer dielectric layers and gate electrode layers alternately stacked over a substrate, a channel conductive layer formed to vertically protrude from the substrate, and a charge blocking layer, a charge trap or charge storage layer, a coupling prevention layer, and a tunnel insulation layer formed between the interlayer dielectric layers and the gate electrode layers and in contact with the channel conductive layer.

In accordance with still another exemplary embodiment of the present invention, a method for fabricating a nonvolatile memory device includes: alternately stacking a plurality of interlay dielectric layers and a plurality of sacrifice layers over a substrate, forming a plurality of channel trenches exposing the substrate by etching the interlayer dielectric layers and the sacrifice layers, forming a plurality of channels by filling a conductive material in the channel trenches, removing the sacrifice layers to form a hole, forming a charge blocking layer and a charge trap or charge storage layer along the surface of the resultant structure including the interlayer dielectric layers, forming a coupling prevention layer at the surface of the charge trap or charge storage layer, forming a tunnel insulation layer over the coupling prevention layer, and filling the hole with a gate electrode.

### BRIEF DESCRIPTION OF THE DRAWINGS

FIG. 1 is a cross-sectional view illustrating a nonvolatile memory device in accordance with a first embodiment of the present invention.

FIGS. 2A to 2D are cross-sectional views illustrating a method for fabricating the nonvolatile memory device in accordance with the first embodiment of the present invention.

FIG. 3 is a sectional view illustrating a nonvolatile memory device in accordance with a second embodiment of the present invention.

FIG. 4 is a cross-sectional view illustrating a nonvolatile memory device in accordance with a third embodiment of the present invention.

FIG. 5 is a cross-sectional view illustrating a nonvolatile memory device in accordance with a fourth embodiment of the present invention.

FIGS. 6A to 6G are cross-sectional views illustrating a method for fabricating the nonvolatile memory device in accordance with the fourth embodiment of the present invention.

FIG. 7 is a cross-sectional view illustrating a nonvolatile memory device in accordance with a fifth embodiment of the present invention.

FIG. 8 is a cross-sectional view illustrating a nonvolatile memory device in accordance with a sixth embodiment of the present invention.

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

### First Embodiment

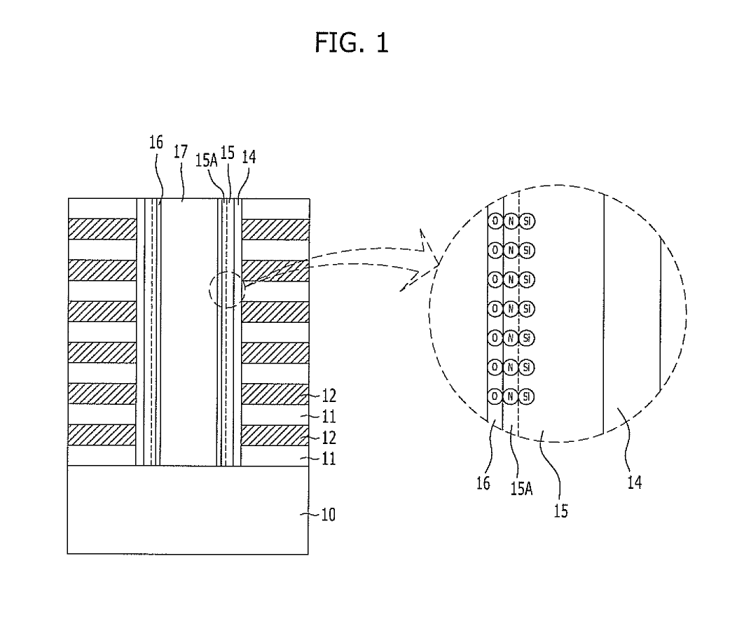

FIG. 1 is a cross-sectional view illustrating a nonvolatile memory device in accordance with a first embodiment of the present invention.

Referring to FIG. 1, a plurality of interlayer dielectric layers 11 and a plurality of gate electrode conductive layers 12 are alternately stacked on a substrate 10 including desired lower structures such as a source line and a lower selection transistor. Here, the interlayer dielectric layers 11 are provided to isolate a plurality of stacked memory cells from each other, and may be formed of oxide. Furthermore, the gate electrode conductive layers 12 may be formed of polysilicon doped with P-type or N-type impurities.

Depending on the number of memory cells to be stacked on the substrate 10, the interlayer dielectric layers 11 and the gate electrode conductive layers are repetitively formed. The interlayer dielectric layers 11 and the gate electrode conductive layers 12 may be respectively formed to have a thickness of 100 Å to 800 Å.

A cell channel portion which is not illustrated in FIG. 1 is formed to pass through the interlayer dielectric layers 11 and the gate electrode conductive layers 12 to expose the substrate 10. A charge blocking layer 14 and a charge trap or charge storage layer 15 are formed on sidewalls of the cell channel portion.

The charge blocking layer 14 is provided to substantially prevent charges from moving in a gate electrode direction through the charge trap or charge storage layer 15, and may include an oxide layer formed by a thermal oxidation process or deposition process. The oxide layer may include any one selected from a silicon oxide layer (SiO₂), a silicon oxide compound layer, and a high dielectric constant material layer. The high dielectric constant material layer includes a single layer formed of any one selected from the group consisting of Al₂O₃, La₂O₃, HfO₂, TiO₂, and ZrO₂ or a compound thereof.

The charge blocking layer 14 may be formed to have such a thickness as to block the gate electrode from the charge trap or charge storage layer 15 depending on electrical characteristics. For example, the charge block layer 14 may be formed to have 100 Å or less thickness at least.

The charge trap or charge storage layer 15 is used as a substantial data storage place, serves to trap charges in a deep-level trap site, and may be formed of nitride. In particular, the charge trap or charge storage layer 15 may be formed of silicon nitride, for example, Si-rich nitride in which the composition of silicon is larger than that of nitride, and the composition ratio of silicon to nitride may be set to 1.33 or less.

A coupling prevention layer 15A is formed on the surface of the charge trap or charge storage layer 15. The coupling prevention layer 15A is formed by nitrifying the surface of the charge trap or charge storage layer 15, and may have a thickness of 10 Å or less.

That is, the inside of the charge trap or charge storage layer 15 is formed at the composition in which silicon is richer than nitrogen. The coupling prevention layer 15A in which nitrogen is selectively compensated is formed on the surface of the charge trap or charge storage layer 15, thereby substantially preventing silicon-oxygen coupling between the charge trap or charge storage layer 15 and a subsequent tunnel insulation layer.

The tunnel insulation layer 16 is formed on the charge trap or charge storage layer 15, and a channel 17 is formed in the cell channel portion. The tunnel insulation layer 16 is provided as an energy barrier layer according to charge tunneling, and formed of oxide. The channel 17 is formed of polysilicon.

As described above, the Si-rich charge trap or charge storage layer 15 in which the composition of silicon is larger than that of nitrogen is formed, and the coupling prevention layer 15A in which nitrogen is compensated is formed on the surface of the charge trap or charge storage layer 15, thereby substantially preventing silicon within the charge trap or charge storage layer 15 from being coupled to oxygen within the tunnel insulation layer 16. Therefore, lack of oxygen within the tunnel insulation layer 16 may be prevented/reduced.

Therefore, an MLC of which the erase operation speed is excellent may be implemented by the Si-rich charge trap or charge storage layer 15, and defects of the tunnel insulation layer 16 may be substantially prevented by the coupling prevention layer 15A formed on the surface of the charge trap or charge storage layer 15. A SONOS device having an excellent retention characteristic may be formed.

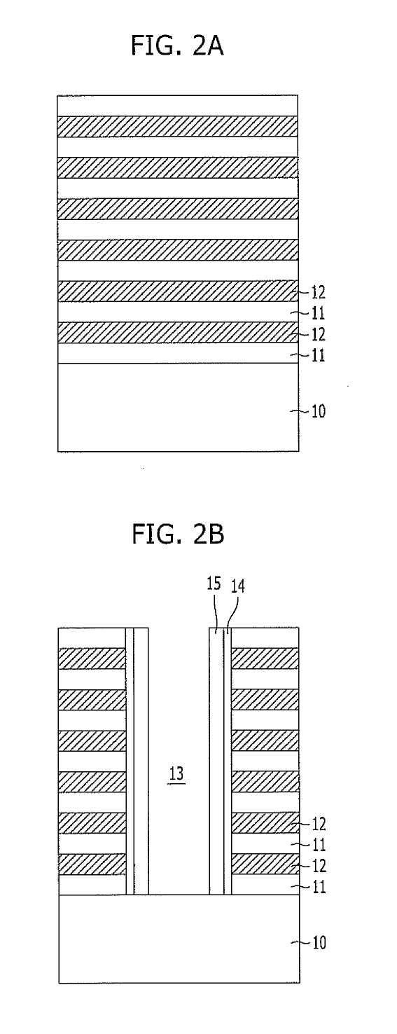

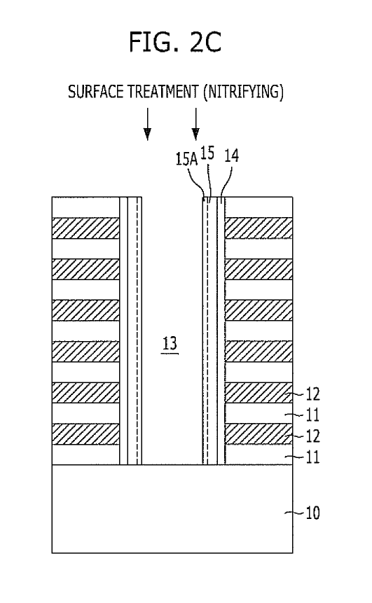

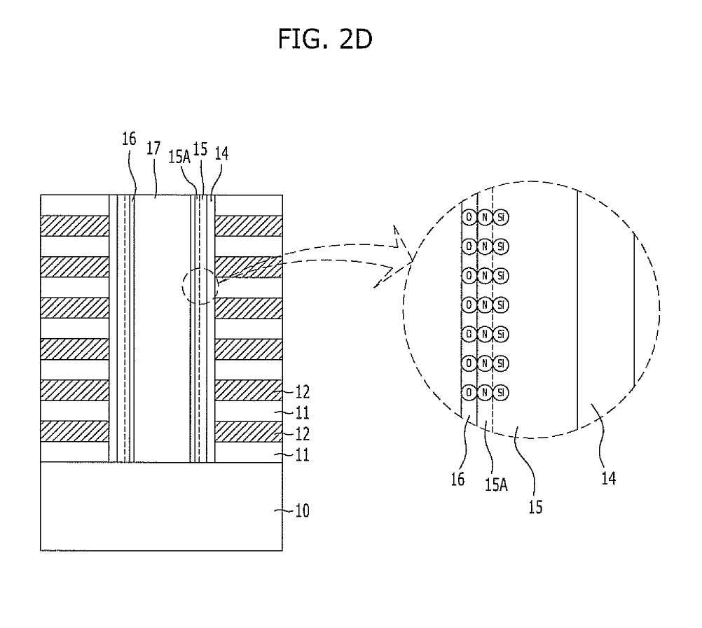

FIGS. 2A to 2D are cross-sectional views illustrating a method for fabricating the nonvolatile memory device in accordance with the first embodiment of the present invention. FIGS. 2A to 2D are cross-sectional views for forming the nonvolatile memory device illustrated in FIG. 1. For illustration purposes, the same reference numerals as those of FIG. 1 are used to describe the method.

Referring to FIG. 2A, a plurality of interlayer dielectric layers 11 and a plurality of gate electrode conductive layers 12 are alternately stacked on a substrate 10 having desired lower structures such as a source line and a lower selection transistor.

Here, the interlayer dielectric layers 11 are provided to isolate a plurality of stacked memory cells from each other, and may be formed of oxide. Furthermore, the gate electrode conductive layers 12 may be formed of polysilicon doped with P-type or N-type impurities.

Depending on the number of memory cells to be stacked on the substrate 10, the interlayer dielectric layers 11 and the gate electrode conductive layers may be repetitively formed.

The interlayer dielectric layers 11 and the gate electrode conductive layers 12 may be respectively formed to have a thickness of 100 Å to 800 Å, and may be formed by chemical vapor deposition (CVD) or atomic layer deposition (ALD).

Referring to FIG. 2B, the interlayer dielectric layers 11 and the gate electrode conductive layers 12 are selectively etched to form a hole 13 exposing the surface of the substrate 10. The hole 13 is provided to form a channel through a subsequent process. Hereafter, the hole 13 is referred to as a cell channel portion 13.

A charge blocking layer 14 is formed on sidewalls of the cell channel portion 13. The charge blocking layer 14 is provided to substantially prevent charges from moving in a gate electrode direction through a charge trap or charge storage layer, and may include an oxide layer formed by a thermal oxidation process or deposition process. The charge blocking layer 14 may be formed of any one selected from a silicon oxide (SiO₂), a silicon oxide compound, and a high dielectric constant material. The high dielectric constant material layer includes a single layer formed of any one selected from the group consisting of Al₂O₃, La₂O₃, HfO₂, TiO₂, and ZrO₂ or a compound thereof. The deposition process may include a CVD process or ALD process.

The charge blocking layer 14 may be formed to have such a thickness as to block the gate electrode from the charge trap or charge storage layer depending on electrical characteristics. For example, the charge block layer 14 may be formed to be 100 Å or less in thickness.

The charge trap or charge storage layer 15 is formed on the charge blocking layer 14. The charge trap or charge storage layer 15 is used as a substantial data storage place, serves to trap charges in a deep-level trap site, and may be formed of nitride.

In particular, the charge trap or charge storage layer 15 may be formed of silicon nitride, for example, Si-rich nitride in which the composition of silicon is larger than that of nitride, and the composition ratio of silicon to nitride may be set to be 1.33 or less.

The deposition method of the charge trap or charge storage layer 15 may include a CVD process or ALD process.

Referring to FIG. 2C, a coupling prevention layer 15A is formed on the surface of the charge trap or charge storage layer 15. The coupling prevention layer 15A may be formed by nitrifying the surface of the charge trap or charge storage layer 15, and may have a thickness of 10 Å or less at least.

The method for nitrifying the surface of the charge trap or charge storage layer 15 may include a plasma process. At this time, any one selected from the group consisting of electron cyclotron resonance (ECR) plasma, inductively coupled plasma (ICP), and radio frequency (RF) plasma may be used as a plasma source, or remote plasma may be used. Furthermore, injected gas may include any one selected from the group consisting of N₂, NO, NO₂, and NH₃ or a mixture of two or more thereof.

As described above, when the coupling prevention layer 15A is formed on the surface of the charge trap or charge storage layer 15, nitrogen is selectively compensated on the surface, while the inside of the charge trap or charge storage layer 15 has a Si-rich composition. Therefore, it may substantially prevent silicon-oxygen coupling between the charge trap or charge storage layer 15 and a subsequent tunnel insulation layer.

Referring to FIG. 2D, a tunnel insulation layer 16 is formed on the coupling prevention layer 15A. The tunnel insulation layer 16 is provided as an energy barrier according to charge tunneling, and may be formed of oxide.

A channel 17 is formed by burying a channel layer in the cell channel portion 13.

As described above, the Si-rich charge trap or charge storage layer 15 in which the composition of silicon is larger than that of nitrogen is formed, and the coupling prevention layer 15A in which nitrogen is compensated is formed by nitrifying the surface of the charge trap or charge storage layer 15, thereby substantially preventing silicon within the charge trap or charge storage layer 15 from being coupled to oxygen within the tunnel insulation layer 16.

Therefore, an MLC of which the erase operation speed is excellent may be implemented by the Si-rich charge trap or charge storage layer 15, and defects of the tunnel insulation layer 16 may be substantially prevented by the coupling prevention layer 15A formed on the surface of the charge trap or charge storage layer 15. Therefore, a SONOS device having an excellent retention characteristic may be formed. Furthermore, since the nitration process is performed only on the surface of the charge trap or charge storage layer 15, the plasma process time is reduced. Therefore, the fabrication time may be shortened, which may reduce the fabrication cost.

### Second Embodiment

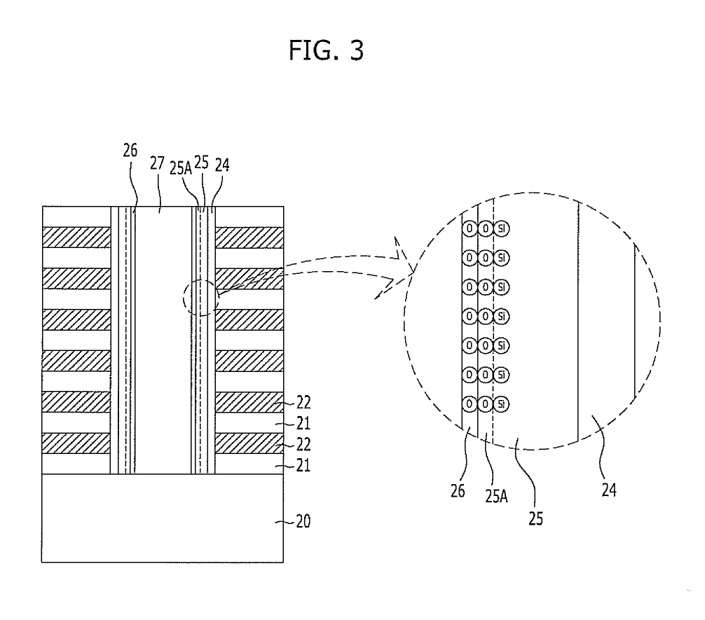

FIG. 3 is a sectional view illustrating a nonvolatile memory device in accordance with a second embodiment of the present invention.

Referring to FIG. 3, a plurality of interlayer dielectric layers 21 and a plurality of gate electrode conductive layers 22 are alternately stacked on a substrate 20 including desired lower structures such as a source line and a lower selection transistor.

A cell channel portion which is not illustrated in FIG. 3 is formed passing through the interlayer dielectric layers 21 and the gate electrode conductive layers 22 to expose the substrate 20. A charge blocking layer 24 and a charge trap or charge storage layer 25 are formed on sidewalls of the cell channel portion.

The charge trap or charge storage layer 25 is used as a substantial data storage place, serves to trap charges in a deep-level trap site, and may be formed of nitride. In particular, the charge trap or charge storage layer 25 may be formed of silicon nitride, for example, Si-rich nitride in which the composition of silicon is larger than that of nitride, and the composition ratio of silicon to nitride may be set to 1.33 or less.

A coupling prevention layer 25A is formed on the surface of the charge trap or charge storage layer 25. The coupling prevention layer 25A is formed by oxidizing the surface of the charge trap or charge storage layer 25, and may have a thickness of 10 Å or less. The method for oxidizing the surface of the charge trap or charge storage layer 25 includes a plasma process or thermal process. At this time, any one selected from the group consisting of ECR, ICP, and RF may be used as a plasma source, or remote plasma may be used. Furthermore, injected gas may include any one selected from the group consisting of O₂, O₃, O* (radical), NO, and NO₂ or a mixture of two or more thereof.

A tunnel insulation layer 26 is formed on the charge trap or charge storage layer 25, and a channel 27 is formed in the cell channel portion. The tunnel insulation layer 26 is provided as an energy barrier layer according to charge tunneling, and formed of oxide. The channel 27 is formed of polysilicon.

As described above, the Si-rich charge trap or charge storage layer 25 in which the composition of silicon is larger than that of nitrogen is formed, and the coupling prevention layer 25A is formed by performing an oxidation treatment on the surface of the charge trap or charge storage layer 25, thereby substantially preventing silicon within the charge trap or charge storage layer 25 from being coupled to oxygen of the tunnel insulation layer 26. Therefore, lack of oxygen within the tunnel insulation layer 26 may be prevented/reduced.

Therefore, an MLC of which the erase operation speed is high may be implemented by the Si-rich charge trap or charge storage layer 25, and defects of the tunnel insulation layer 26 may be substantially prevented by the coupling prevention layer 25A formed on the surface of the charge trap or charge storage layer 25. A SONOS device having an excellent retention characteristic may be formed.

### Third Embodiment

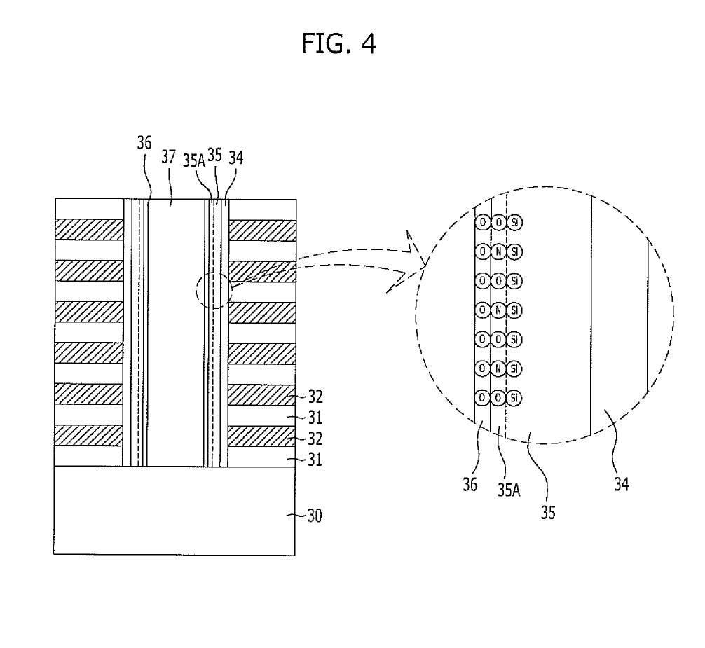

FIG. 4 is a cross-sectional view illustrating a nonvolatile memory device in accordance with a third embodiment of the present invention.

Referring to FIG. 4, a plurality of interlayer dielectric layers 31 and a plurality of gate electrode conductive layers 32 are alternately stacked on a substrate 30 including desired lower structures such as a source line and a lower selection transistor.

A cell channel portion which is not illustrated in FIG. 4 is formed passing through the interlayer dielectric layers 31 and the gate electrode conductive layers 32 to expose the substrate 30. A charge blocking layer 34 and a charge trap or charge storage layer 35 are formed on sidewalls of the cell channel portion.

The charge trap or charge storage layer 35 is used as a substantial data storage place, serves to trap charges in a deep-level trap site, and may be formed of nitride. In particular, the charge trap or charge storage layer 35 may be formed of silicon nitride, for example, Si-rich nitride in which the composition of silicon is larger than that of nitride, and the composition ratio of silicon to nitride may be set to 1.33 or less.

A coupling prevention layer 35A is formed on the surface of the charge trap or charge storage layer 35. The coupling prevention layer 35A is formed by nitrifying the surface of the charge trap or charge storage layer 35, and may have a thickness of 10 Å or less. The method for nitrifying the surface of the charge trap or charge storage layer 35 includes a plasma process or thermal process. At this time, any one selected from the group consisting of ECR, ICP, and RF may be used as a plasma source, or remote plasma may be used. Furthermore, injected gas may include any one selected from the group consisting of O₂, O₃, O* (radical), N₂, NO, NO₂, and NH₃ or a mixture of two or more thereof.

A tunnel insulation layer 36 is formed on the charge trap or charge storage layer 35, and a channel 37 is formed in the cell channel portion. The tunnel insulation layer 36 is provided as an energy barrier layer according to charge tunneling, and formed of oxide. The channel 37 is formed of polysilicon.

As described above, the Si-rich charge trap or charge storage layer 35 in which the composition of silicon is larger than that of nitrogen is formed, and the coupling prevention layer 35A is formed by performing a nitrification treatment on the surface of the charge trap or charge storage layer 35, thereby substantially preventing silicon within the charge trap or charge storage layer 35 from being coupled to oxygen of the tunnel insulation layer 36. Therefore, lack of oxygen within the tunnel insulation layer 36 may be prevented/reduced.

Therefore, an MLC of which the erase operation speed is high may be implemented by the Si-rich charge trap or charge storage layer 35, and defects of the tunnel insulation layer 36 may be substantially prevented by the coupling prevention layer 35A formed on the surface of the charge trap or charge storage layer 35. A SONOS device having an excellent retention characteristic may be formed.

### Fourth Embodiment

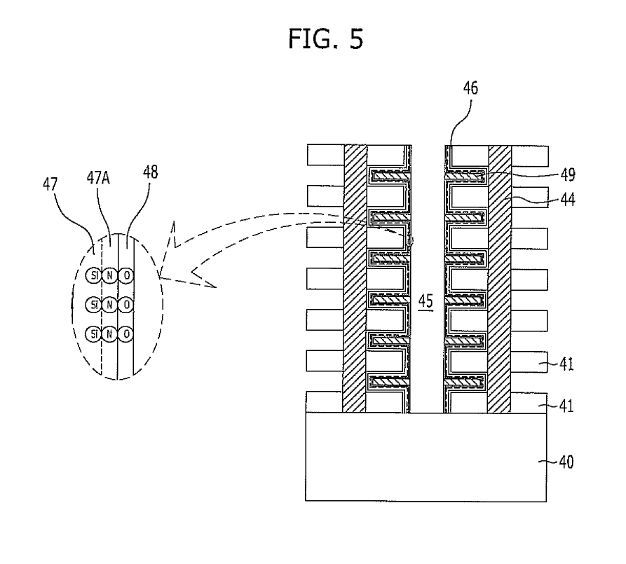

FIG. 5 is a cross-sectional view illustrating a nonvolatile memory device in accordance with a fourth embodiment of the present invention.

Referring to FIG. 5, a plurality of interlayer dielectric layers 41 and a plurality of gate electrodes 49 are alternately stacked on a substrate 40, and a charge blocking layer 46, a charge trap or charge storage layer 47, a coupling prevention layer 47A, and a tunnel insulation layer 48 are interposed between the interlayer dielectric layers 41 and the gate electrodes 49. The gate electrodes 49 include polysilicon or a metallic material.

The charge trap or charge storage layer 47 is used as a substantial data storage place, serves to trap charges in a deep-level trap site, and may be formed of nitride. In particular, the charge trap or charge storage layer 47 may be formed of silicon nitride, for example, Si-rich nitride in which the composition of silicon is larger than that of nitride, and the composition ratio of silicon to nitride may be set to 1.33 or less.

The coupling prevention layer 47A is formed by nitrifying the surface of the charge trap or charge storage layer 47, and may have a thickness of 10 Å or less at least.

As described above, the inside of the charge trap or charge storage layer 47 has a composition in which silicon is richer than nitrogen. The coupling prevention layer 47A in which nitrogen is selectively compensated is formed on the surface of the charge trap or charge storage layer 47, thereby substantially preventing silicon-oxygen coupling between the charge trap or charge storage layer 47 and the subsequent tunnel insulation layer 48.

A channel 44 is formed so as to be in contact with side surfaces of the interlayer dielectric layers 41 and the charge blocking layer 46.

As described above, the Si-rich charge trap or charge storage layer 47 in which the ratio of silicon is larger than that of nitrogen is formed, and the coupling prevention layer 47A in which nitrogen is compensated is formed on the surface of the charge trap or charge storage layer 47, thereby substantially preventing silicon within the charge trap or charge storage layer 47 from being coupled to oxygen within the tunnel insulation layer 48. Therefore, it may substantially prevent lack of oxygen within the tunnel insulation layer 48.

Therefore, an MLC of which the erase operation speed is high may be implemented by the Si-rich charge trap or charge storage layer 47, and defects of the tunnel insulation layer 48 may be substantially prevented by the coupling prevention layer 47A formed on the surface of the charge trap or charge storage layer 47. Therefore, A SONOS device having an excellent retention characteristic may be formed.

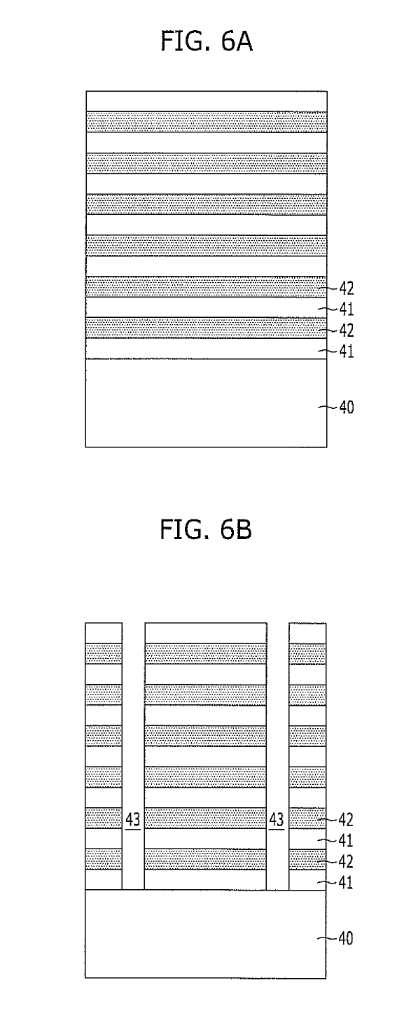

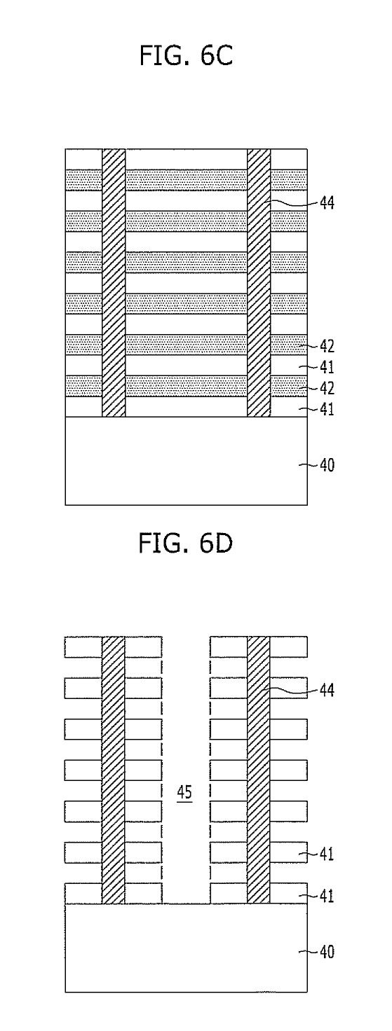

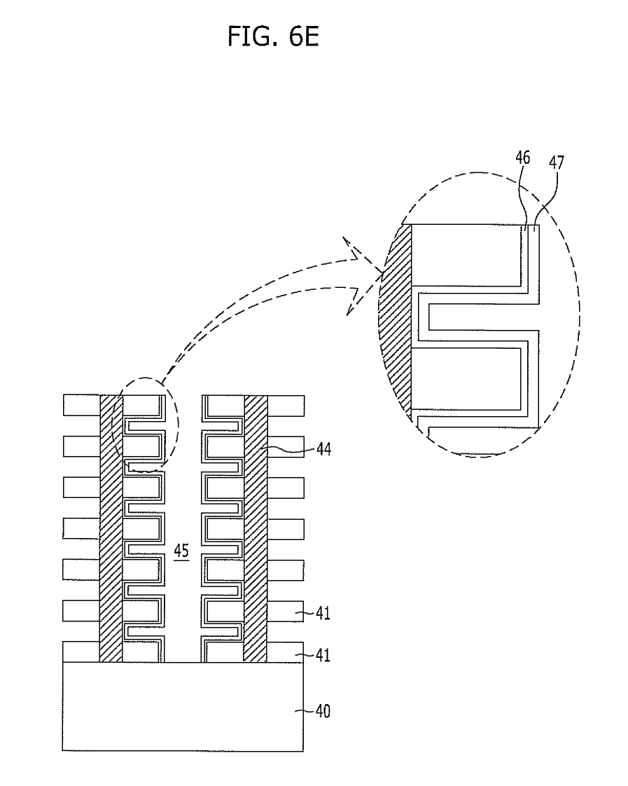

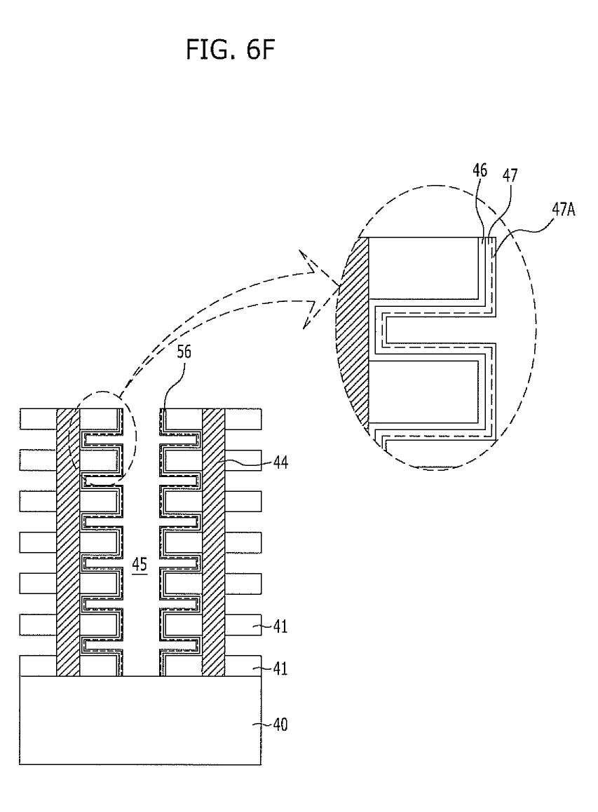

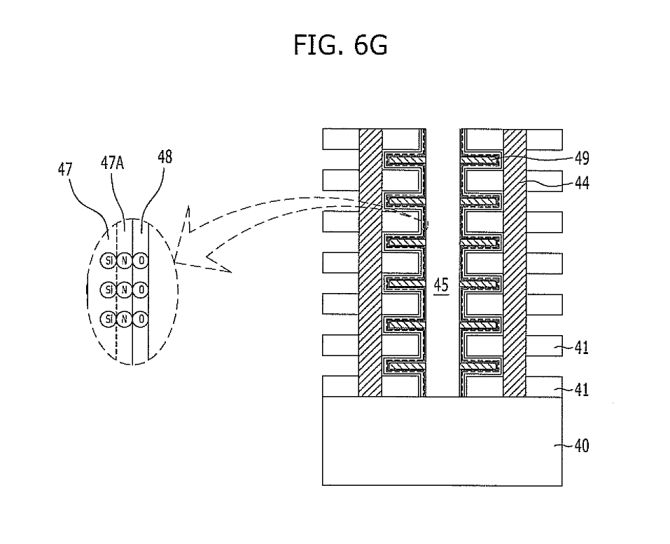

FIGS. 6A to 6G are cross-sectional views illustrating a method for fabricating the nonvolatile memory device in accordance with the fourth embodiment of the present invention. FIGS. 6A to 6G are cross-sectional views for forming the nonvolatile memory device illustrated in FIG. 5. For illustration purposes, the same reference numerals as those of FIG. 5 are used to describe the method.

Referring to FIG. 6A, a plurality of interlayer dielectric layers 41 and a plurality of sacrifice layers 42 are alternately stacked on a substrate 40. The interlayer dielectric layers 41 are provided to isolate a plurality of subsequent gate electrodes from each other, and may be formed of oxide. The sacrifice layers 42 are provided to secure a space for forming gate electrodes, and formed of a material having an etching selectivity with respect to the interlayer dielectric layers 41. Desirably, the sacrifice layers 42 may be formed of nitride.

Referring to FIG. 6B, the interlayer dielectric layers 41 and the sacrifice layers 42 are etched to form a plurality of channel trenches 43 which exposes the substrate 40.

Referring to FIG. 6C, a conductive material is buried in the channel trenches 43 to form a plurality of channels 44. At this time, the conductive material includes polysilicon.

Referring to FIG. 6D, the interlayer dielectric layers 41 and the sacrifice layers 42 between the channels 44 are etched to form a sacrifice layer removal trench 45 (shown by a dotted line) which exposes the substrate 40.

The sacrifice layers 42 exposed through the sacrifice layer removal trench 45 are selectively removed. The sacrifice layers 42 may be removed by wet etching.

As the sacrifice layers 42 are removed, sidewalls of the sacrifice layer removal trench 45 have uneven (i.e. raised columns and grooves) patterns.

Referring to FIG. 6E, a charge blocking layer 46 and a charge trap or charge storage layer 47 are formed along the entire surface of the resultant structure, that is, the uneven patterns of the resultant structure. The charge trap or charge storage layer 47 is used as a substantial data storage place, serves to trap charges in a deep-level trap site, and may be formed of nitride.

In particular, the charge trap or charge storage layer 47 may be formed of silicon nitride, for example, Si-rich nitride in which the composition of silicon is larger than that of nitride, and the composition ratio of silicon to nitride may be set to 1.33 or less at least.

The method for depositing the charge trap or charge storage layer 47 includes a CVD process or ALD process.

Referring to FIG. 6F, the coupling prevention layer 47A is formed on the surface of the charge trap or charge storage layer 47.

The coupling prevention layer 47A may be formed by nitrifying the surface of the charge trap or charge storage layer 47, and may have a thickness of 10 Å or less at least. The method for nitrifying the surface of the charge trap or charge storage layer 47 may include a plasma process. At this time, any one selected from the group consisting of ECR, ICP, and RF may be used as a plasma source, or remote plasma may be used. Furthermore, injected gas may include any one selected from the group consisting of N₂, NO, NO₂, and NH₃ or a mixture of two or more thereof.

As described above, when the coupling prevention layer 47A is formed on the surface of the charge trap or charge storage layer 47, nitrogen is selectively compensated on the surface, while the inside of the charge trap or charge storage layer 47 has a Si-rich composition. Therefore, it may substantially prevent silicon-oxygen coupling between the charge trap or charge storage layer 47 and a subsequent tunnel insulation layer.

Referring to FIG. 6G, a tunnel insulation layer 48 is formed on the coupling prevention layer 47A.

A plurality of gate electrodes 49 are formed on the tunnel insulation layer 48 so as to fill grooves of the patterns to even a surface of the patterns. The gate electrodes 49 may be formed of polysilicon or a metallic material.

### Fifth Embodiment

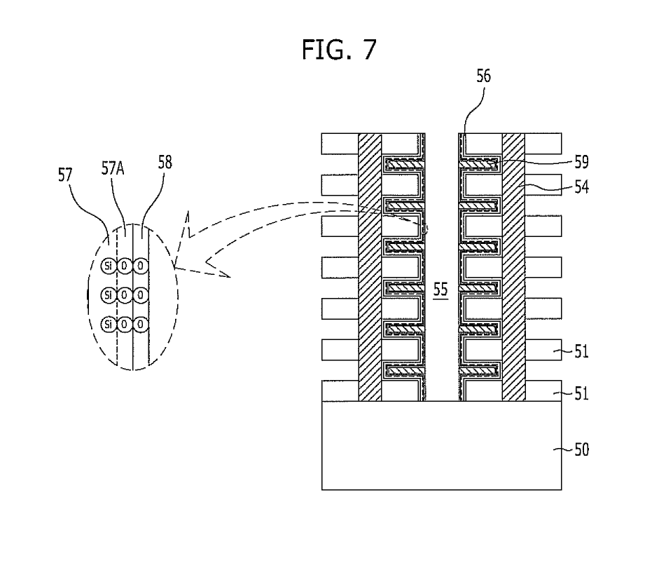

FIG. 7 is a cross-sectional view illustrating a nonvolatile memory device in accordance with a fifth embodiment of the present invention.

Referring to FIG. 7, a plurality of interlayer dielectric layers 51 and a plurality of gate electrodes 59 are alternately stacked on a substrate 50, and a charge blocking layer 56, a charge trap or charge storage layer 57, a coupling prevention layer 57A, and a tunnel insulation layer 58 are interposed between the interlayer dielectric layers 51 and the gate electrodes 59.

The charge trap or charge storage layer 57 is used as a substantial data storage place, serves to trap charges in a deep-level trap site, and may be formed of nitride. In particular, the charge trap or charge storage layer 57 may be formed of silicon nitride, for example, Si-rich nitride in which the composition of silicon is larger than that of nitride, and the composition ratio of silicon to nitride may be set to 1.33 or less at least.

The coupling prevention layer 57A may be formed by oxidizing the surface of the charge trap or charge storage layer 57, and may have a thickness of 10 Å or less at least. The method for oxidizing the surface of the charge trap or charge storage layer 57 may include a plasma process or thermal process. At this time, any one selected from the group consisting of ECR, ICP, and RF may be used as a plasma source, or remote plasma may be used. Furthermore, injected gas may include any one selected from the group consisting of O₂, O₃, O* (radical), NO, and NO₂ or a mixture of two or more thereof.

### Sixth Embodiment

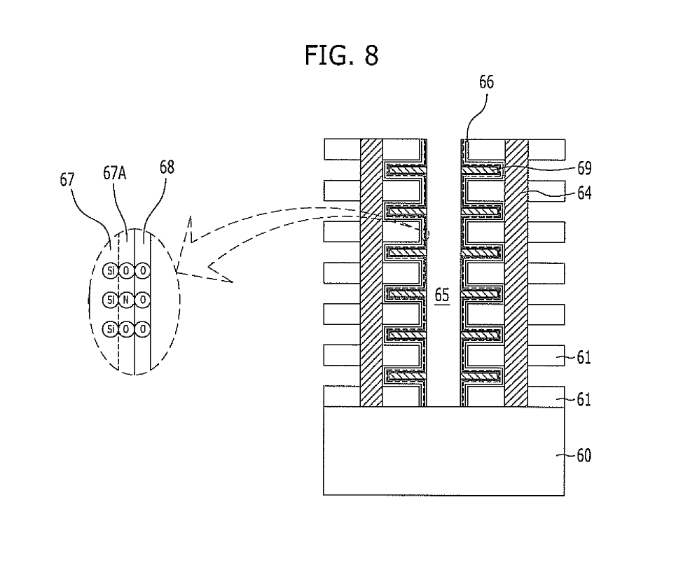

FIG. 8 is a cross-sectional view illustrating a nonvolatile memory device in accordance with a sixth embodiment of the present invention.

Referring to FIG. 8, a plurality of interlayer dielectric layers 61 and a plurality of gate electrodes 69 are alternately stacked on a substrate 60, and a charge blocking layer 66, a charge trap or charge storage layer 67, a coupling prevention layer 67A, and a tunnel insulation layer 68 are interposed between the interlayer dielectric layers 61 and the gate electrodes 69.

The charge trap or charge storage layer 67 is used as a substantial data storage place, serves to trap charges in a deep-level trap site, and may be formed of nitride. In particular, the charge trap or charge storage layer 67 may be formed of silicon nitride, for example, Si-rich nitride in which the composition of silicon is larger than that of nitride, and the composition ratio of silicon to nitride may be set to 1.33 or less.

The coupling prevention layer 67A may be formed by nitrifying the surface of the charge trap or charge storage layer 67, and may have a thickness of 10 Å or less. The method for nitrifying the surface of the charge trap or charge storage layer 67 may include a plasma process or thermal process. At this time, any one selected from the group consisting of ECR, ICP, and RF may be used as a plasma source, or remote plasma may be used. Furthermore, injected gas may include any one selected from the group consisting of O₂, O₃, O* (radical), N₂ NO, NO₂, and NH₃ or a mixture of two or more thereof.

The nonvolatile memory devices in accordance with the second and third embodiments of the present invention may be fabricated according to the same process as that of the first embodiment of the present invention, and the nonvolatile memory devices in accordance with the fifth and sixth embodiments of the present invention may be fabricated according to the same process as that of the fourth embodiment of the present invention.

In accordance with the embodiments of the present invention, the Si-rich charge trap or charge storage layer in which the composition of silicon is larger than that of nitrogen is formed, and the coupling prevention layer is formed on the surface of the charge trap or charge storage layer, thereby substantially preventing silicon within the charge trap or charge storage layer from being coupled to oxygen within the tunnel insulation layer. Therefore, lack of oxygen within the tunnel insulation layers may be substantially prevented.

Furthermore, an MLC of which the erase operation speed is high may be implemented by the Si-rich charge trap or charge storage layer, and defects of the tunnel insulation layer may be prevented by the coupling prevention layer formed on the surface of the charge trap or charge storage layer. Therefore, it may form a SONOS device having an excellent retention characteristic.

Furthermore, since nitrifying treatment is performed only on the surface of the charge trap or charge storage layer, the plasma process time is reduced. Therefore, the fabrication time may be shortened, which may reduce the fabrication cost.

While the present invention has been described with respect to the specific embodiments, it will be apparent to those skilled in the art that various changes and modifications may be made without departing from the spirit and scope of the invention as defined in the following claims.

What is claimed is:

1. A nonvolatile memory device comprising:
a plurality of interlayer dielectric layers and conductive layers for gate electrodes alternately stacked over a substrate;
a channel trench formed through the interlayer dielectric layers and the conductive layers to expose the substrate;
a charge blocking layer and a charge trap or charge storage layer formed on sidewalls of the trench;
a coupling prevention layer formed at the surface of the charge trap or charge storage layer; and
a tunnel insulation layer formed over the coupling prevention layer.

2. The nonvolatile memory device of claim 1, wherein the charge trap or charge storage layer comprises a Si-rich nitride layer in which the composition ratio of silicon is higher than that of nitrogen.

3. The nonvolatile memory device of claim 2, wherein the composition ratio of silicon to nitrogen is 1.33 or less.

4. The nonvolatile memory device of claim 1, wherein the coupling prevention layer is formed by performing any one treatment selected from nitration, oxidation, and nitrification on the surface of the charge trap or charge storage layer.

5. A method for fabricating a nonvolatile memory device, comprising:
alternately stacking a plurality of interlayer dielectric layers and conductive layers for gate electrodes over a substrate;
forming a channel trench exposing the substrate by etching the plurality of interlayer dielectric layers and the plurality of conductive layers;
forming a charge blocking layer on sidewalls of the hole;
forming a charge trap or charge storage layer over the charge blocking layer;
forming a coupling prevention layer at the surface of the charge trap or charge storage layer; and
forming a tunnel insulation layer over the coupling prevention layer.

6. The method of claim 5, wherein the charge trap or charge storage layer includes a Si-rich nitride layer in which the composition ratio of silicon is higher than that of nitrogen.

7. The method of claim 5, wherein, in the forming of the coupling prevention layer, any one treatment selected from nitration, oxidation, and nitrification is performed on the surface of the charge trap or charge storage layer.

8. The method of claim 5, wherein the forming of the coupling prevention layer comprises a plasma process or thermal process.

9. The method of claim 7, wherein the nitration treatment is performed through a plasma process using any one selected from the group consisting of N₂, NO, NO₂, and NH₃ or a mixture of two or more thereof.

10. The method of claim 7, wherein the oxidation treatment is performed through a plasma process using any one selected from the group consisting of O₂, O₃, O* (radical), NO, and NO₂ or a mixture of two or more thereof.

11. The method of claim 7, wherein the nitrification treatment is performed through a plasma process using any one selected from the group consisting of O₂, O₃, O* (radical), N₂, NO, NO₂, and NH₃ or a mixture of two or more thereof.

12. A nonvolatile memory device comprising:
a plurality of interlayer dielectric layers and gate electrode layers alternately stacked over a substrate;
a channel conductive layer formed to vertically protrude from the substrate; and
a charge blocking layer, a charge trap or charge storage layer, a coupling prevention layer, and a tunnel insulation layer formed between the interlayer dielectric layers and the gate electrode layers and in contact with the channel conductive layer.

13. The nonvolatile memory device of claim 12, wherein the charge trap or charge storage layer comprises a Si-rich nitride layer in which the composition ration of silicon is higher than that of nitrogen.

14. The nonvolatile memory device of claim 13, wherein the composition ratio of silicon to nitrogen is 1.33 or less.

15. The nonvolatile memory device of claim 12, wherein the coupling prevention layer is formed by performing any one treatment selected from nitration, oxidation, and nitrification over the surface of the charge trap or charge storage layer.

16. A method for fabricating a nonvolatile memory device, comprising:
alternately stacking a plurality of interlay dielectric layers and a plurality of sacrifice layers over a substrate;
forming a plurality of channel trenches exposing the substrate by etching the interlayer dielectric layers and the sacrifice layers;
forming a plurality of channels by filling a conductive material in the channel trenches;
removing the sacrifice layers to form a hole;
forming a charge blocking layer and a charge trap or charge storage layer along the surface of the resultant structure including the interlayer dielectric layers;
forming a coupling prevention layer at the surface of the charge trap or charge storage layer;
forming a tunnel insulation layer over the coupling prevention layer; and
filling the hole with a gate electrode.

17. The method of claim 16, wherein the charge trap or charge storage layer includes a Si-rich nitride layer in which the composition ratio of silicon is higher than that of nitrogen.

18. The method of claim 16, wherein, in the forming of the coupling prevention layer, any one treatment selected from nitration, oxidation, and nitrification is performed over the surface of the charge trap or charge storage layer.

19. The method of claim 16, wherein the forming of the coupling prevention layer comprises a plasma process or thermal process.

20. The method of claim 19, wherein, the plasma process is performed using any one selected from the group consisting of O₂, O₃, O* (radical), N₂, NO, NO₂, and NH₃ or a mixture of two or more thereof.
